(19) United States
(12) Patent Application Publication
(10) Pub. No.: US 2026/0271448 A1
(43) Pub. Date: Sep. 10, 2026

(54) LED PACKAGING STRUCTURE AND LIGHT EMITTING ASSEMBLY

(71) Applicant: ADVANCED OPTOELECTRONIC TECHNOLOGY, INC., Hsinchu County (TW)

(72) Inventors: Hsin-Ting Hung, Hsinchu (TW); Chuang-Yu Hsieh, Hsinchu (TW); Yu-Chia Chen, Hsinchu (TW); Chen-Wei Lin, Hsinchu (TW); Hao-Hsiang Hsieh, Hsinchu (TW)

(21) Appl. No.: 19/231,868

(22) Filed: Jun. 9, 2025

(30) Foreign Application Priority Data
Mar. 10, 2025 (CN) 202510278621.4

(51) Int. Cl. H10H 20/857; H10H 20/85; H10H 20/853

(52) U.S. Cl. CPC H10H 20/857; H10H 20/8504; H10H 20/853

(57) ABSTRACT

The disclosure provides an LED packaging structure and a light emitting assembly. The LED packaging structure includes a conductive structure, an LED chip, and a packaging body. The LED chip is electrically connected to the conductive structure. The packaging body encapsulates the conductive structure, wherein the packaging body has a top surface and a bottom surface opposite to the top surface, and an outer side surface connecting between the top surface and the bottom surface. A shape of the outer side surface is a step shape. The conductive structure has an electrical contact terminal, and the electrical contact terminal is exposed from the packaging body. The advantageous effects of the disclosure are that the LED packaging structure has good heat dissipation effect, and the conductive structure and the packaging body are not easily separated from each other.

### FIELD

The disclosure relates to the LED field, specifically, to an LED packaging structure and a light emitting assembly.

### BACKGROUND

In some known technologies, LED packaging structures have poor heat dissipation capability, and the packaging shell of the LED packaging structures are prone to crack due to thermal stress, or separation between the conductive metal parts and the packaging shell of the packaging structure.

### SUMMARY OF THE INVENTION

The disclosure provides an LED packaging structure and a light emitting assembly.

In a first aspect, an embodiment of the disclosure provide an LED packaging structure. The LED packaging structure includes a conductive structure, an LED chip, and a packaging body. The LED chip is electrically connected to the conductive structure. The packaging body encapsulates the conductive structure, wherein the packaging body has a top surface and a bottom surface opposite to the top surface, and an outer side surface connecting between the top surface and the bottom surface. A shape of the outer side surface is a step shape. The conductive structure has an electrical contact terminal, and the electrical contact terminal is exposed from the packaging body.

In a second aspect, an embodiment of the disclosure provide a light emitting assembly. The light emitting assembly includes a circuit board and the LED packaging structure described above. The electrical contact terminal of the LED packaging structure is soldered and connected to the circuit board to electrically connect the LED chip to the circuit board.

In the LED packaging structure of the disclosure, by making the outer side surface of the packaging body in a step shape, it facilitates thermal stress release, reducing the problem of packaging body cracking or delamination between the packaging body and the conductive structure due to thermal stress during use of the LED packaging structure. Additionally, the step-shaped outer side surface increases the surface area, improving the heat dissipation capability of the LED packaging structure.

### BRIEF DESCRIPTION OF THE DRAWINGS

FIG. 1 is a perspective view of an LED packaging structure according to an embodiment of the present disclosure.

FIG. 2 is another perspective view of the LED packaging structure shown in FIG. 1.

FIG. 3 is an exploded view of the LED packaging structure shown in FIG. 1.

FIG. 4 is a sectional view along line A-A of the LED packaging structure shown in FIG. 1.

FIG. 5 is a front view of the LED packaging structure shown in FIG. 1.

FIG. 6 is a sectional view along line B-B of the LED packaging structure shown in FIG. 5.

FIG. 7 is a perspective view of one part of a conductive structure, (a positive terminal part, shown in FIG. 3.

FIG. 8 is a sectional view along line C-C of the LED packaging structure shown in FIG. 5.

FIG. 9 is a schematic view of a light emitting assembly according to an embodiment of the present disclosure.

FIG. 10 is a sectional view along line D-D of the light emitting assembly shown in FIG. 9.

FIG. 11 is a perspective view of an LED packaging structure according to another embodiment of the present disclosure.

FIG. 12 is another perspective view of the LED packaging structure shown in FIG. 11.

FIG. 13 is a top view of the LED packaging structure shown in FIG. 11.

FIG. 14 is a bottom view of the LED packaging structure shown in FIG. 11.

FIG. 15 is an exploded view of the LED packaging structure shown in FIG. 11.

FIG. 16 is a sectional view along line E-E of the LED packaging structure shown in FIG. 13.

### DETAILED DESCRIPTION

The technical scheme in the embodiment of the disclosure will be described in combination with the attached drawings in the embodiment of the application. Obviously, the described embodiments are only part of the embodiments of the application, not all embodiments.

It should be noted that when an element is said to be “fixed to” another element, it can be directly on another element or there can be an intervening element. When a component is “connected” to another component, it can be directly connected to another component or there may be intermediate components at the same time. When a component is “set on” another component, it can be set directly on another component or there may be intervening components at the same time. The terms “vertical,” “horizontal,” “left,” “right,” and similar expressions used in this paper are for illustrative purposes only.

Unless otherwise defined, all technical and scientific terms used herein have the same meanings as those commonly understood by those skilled in the technical field of the application. The terms used in the specification of the application herein are only for the purpose of describing specific embodiments and are not intended to limit the application. The term “and/or” as used herein includes any and all combinations of one or more related listed items.

Some embodiments of the disclosure are described in detail. Without conflict, the following embodiments and features in the embodiments can be combined with each other.

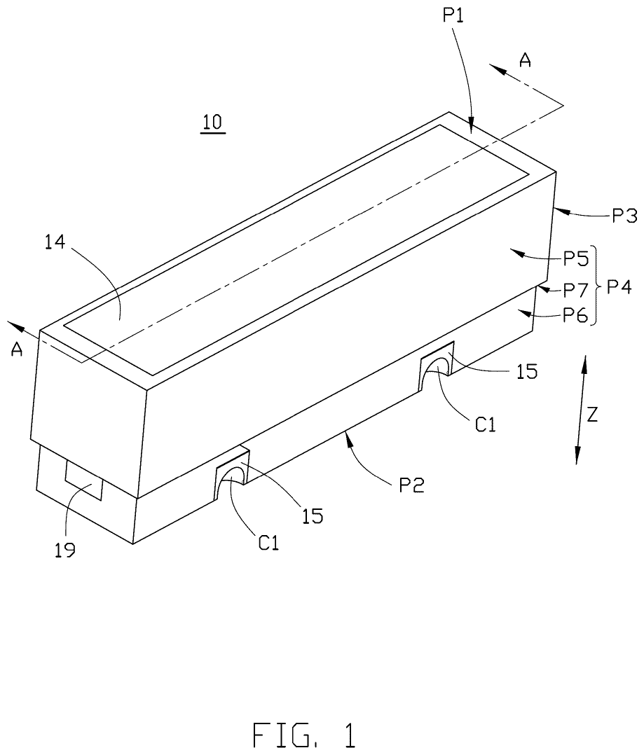

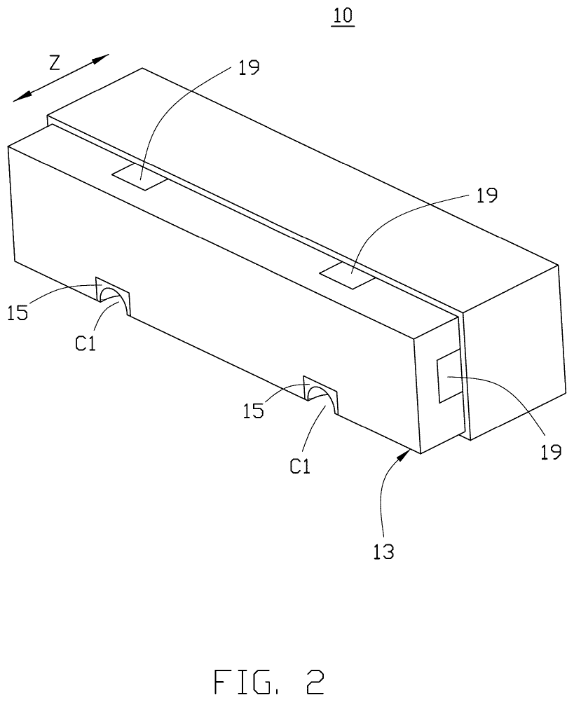

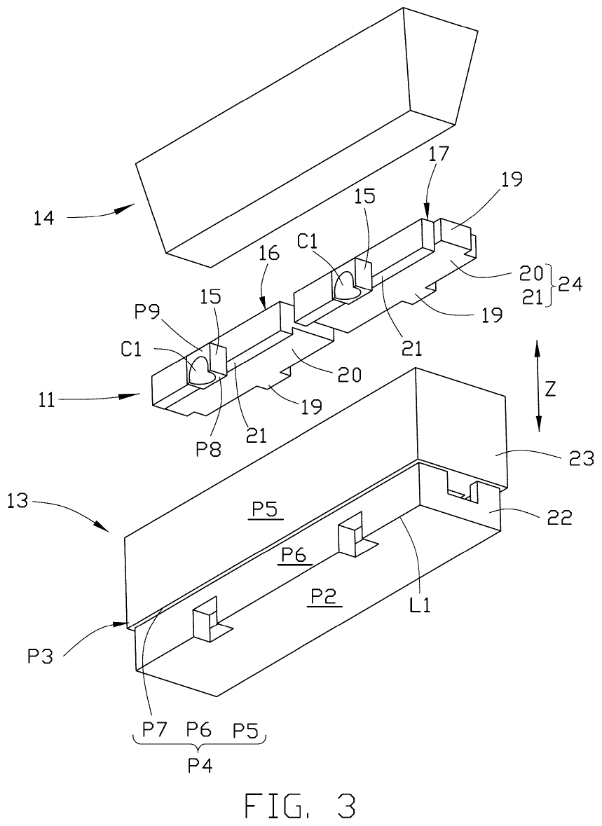

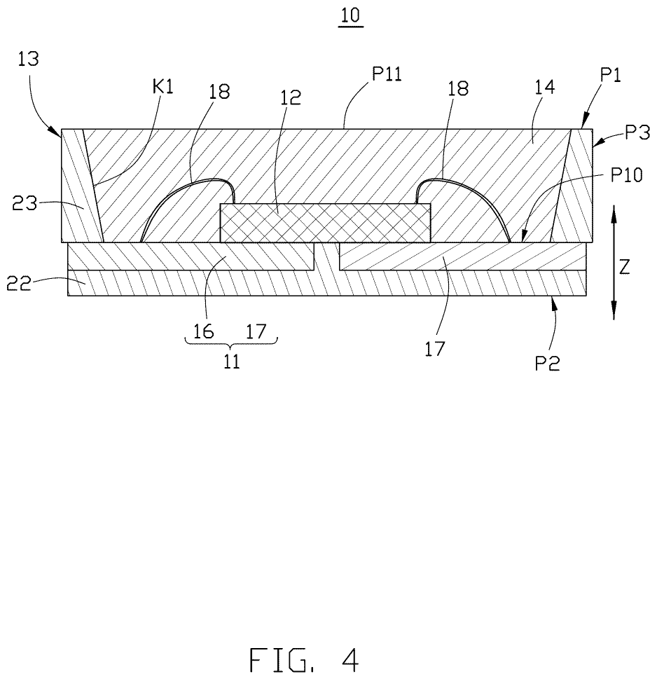

FIG. 1 is a perspective view of an LED packaging structure 10 according to this embodiment. FIG. 2 is another perspective view of the LED packaging structure 10 of FIG. 1. FIG. 3 is an exploded view of the LED packaging structure 10 of FIG. 1. FIG. 4 is a sectional view along line A-A of the LED packaging structure 10 of FIG. 1.

Referring to FIGS. 1-4, this embodiment provides the LED packaging structure 10, which is a side-emitting type LED packaging structure.

The LED packaging structure 10 includes a conductive structure 11, an LED chip 12, a packaging body 13, and a sealing body 14.

The LED chip 12 is electrically connected to the conductive structure 11. The LED chip 12 can be connected to an external circuit through the conductive structure 11. The packaging body 13 encapsulates the conductive structure 11. The packaging body 13 has a top surface P1 and a bottom surface P2 opposite to the top surface, and an outer side surface P3 located between and connected the top surface P1 and the bottom surface P2. The conductive structure 11 includes an electrical contact terminals 15. The electrical contact terminals 15 expose from the packaging body 13 for electrically connecting the LED packaging structure 10 to the external circuit.

A shape of the outer side surface P3 is a step shape. In the embodiment, the outer side surface P3 comprises four surfaces. The four surfaces connect at the beginning and end, forming a rectangular cylindrical annular surface. At least one of the four surfaces of the outer side surface P3 can be in the step shape.

In the LED packaging structure 10 of the embodiment, by making the outer side surface P3 of the packaging body 13 in a step shape, it facilitates thermal stress release, reducing the problem of packaging body 13 cracking or delamination between the packaging body 13 and the conductive structure 11 due to thermal stress during use. Additionally. The step-shaped outer side surface P3 increases a surface area, improving the heat dissipation capability of the LED packaging structure 10, which helps to extend its service life.

Referring to FIGS. 3 and 4, in this embodiment, the conductive structure 11 includes two electrically insulating parts, one of two electrically insulating parts is a positive terminal part 16 for connecting to a positive electrode of the LED chip 12, the other one of two electrically insulating parts is a negative terminal part 17 for connecting to a negative electrode of the LED chip 12. One electrical contact terminal 15 is disposed on a side of the positive part 16 for connecting to a positive electrode of the external circuit. The other electrical contact terminal 15 is disposed on a side of the negative terminal part 17 for connecting to a negative electrode of the external circuit. The LED chip 12 can be stacked on the conductive structure 11.

A sealing body 14 is formed by filling gel in a receiving hole K1 enclosed by the packaging body 13 and the conductive structure 11. The sealing body 14 seals the LED chip 12 inside the LED packaging structure 10. The sealing body 14 can be made of light-transmitting material, such that light emitted by the LED chip 12 can pass through the sealing body 14. A phosphor layer can be provided on an outer surface of the sealing body 14.

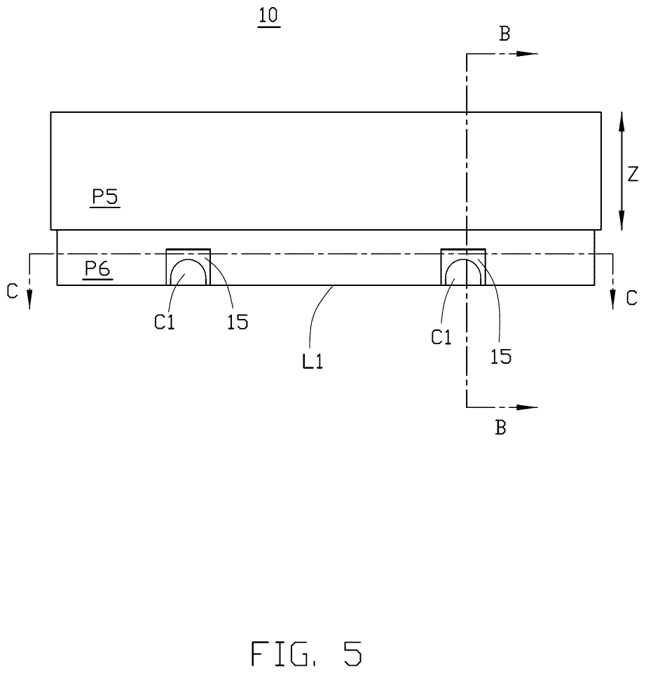

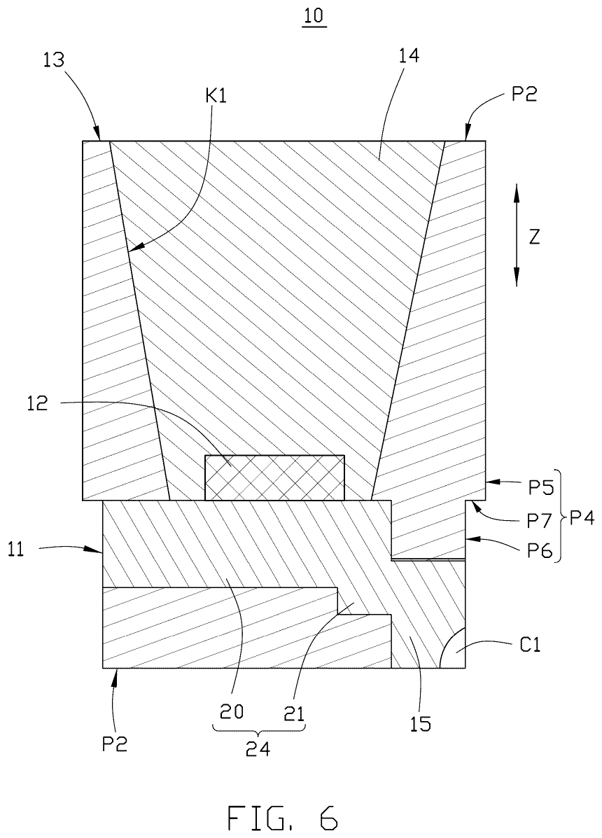

FIG. 5 is a front view of the LED packaging structure 10 of FIG. 1. FIG. 6 is a sectional view along line B-B of the LED packaging structure 10 of FIG. 5.

Referring to FIGS. 6 and 1, in this embodiment, one side surface of the outer side surface P3 of the packaging body 13 is a mounting side surface P4, the mounting side surface P4 is a step shape surface. The mounting side surface P4 includes a first surface region P5, a second surface region P6, and a step surface P7. The step surface P7 connects and locates between the first surface region P5 and the second surface region P6. Optionally, both the first surface region P5 and the second surface region P6 are parallel to a light-emitting direction of the LED packaging structure 10. In this state, the step surface P7 is perpendicular to the first surface region P5 and the second surface region P6. The second surface region P6 is recessed relative to the first surface region P5.

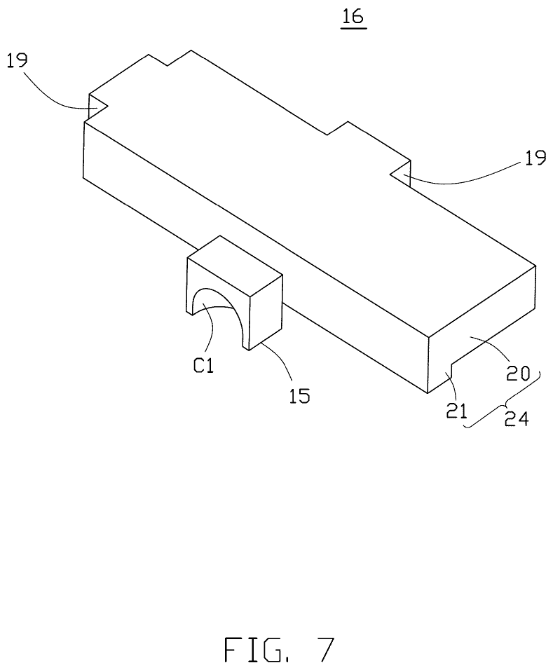

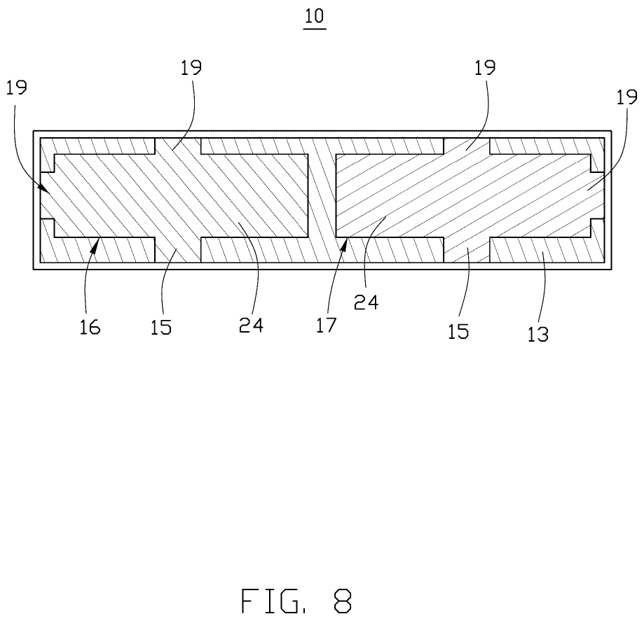

FIG. 7 is a perspective view of one part of the conductive structure 11 (taking the positive terminal part 16 as an example) of FIG. 3. FIG. 8 is a sectional view along line C-C of FIG. 5.

Referring to FIGS. 3 and 5-7, the positive terminal part 16 of the conductive structure 11 includes a conductive plate 24 and an electrical contact terminal 15.

The electrical contact terminal 15 is located at the intersection between the bottom surface P2 and the second surface region P6 of the packaging body 13, and the electrical contact terminal 15 is exposed from the bottom surface P2 and the second surface region P6.

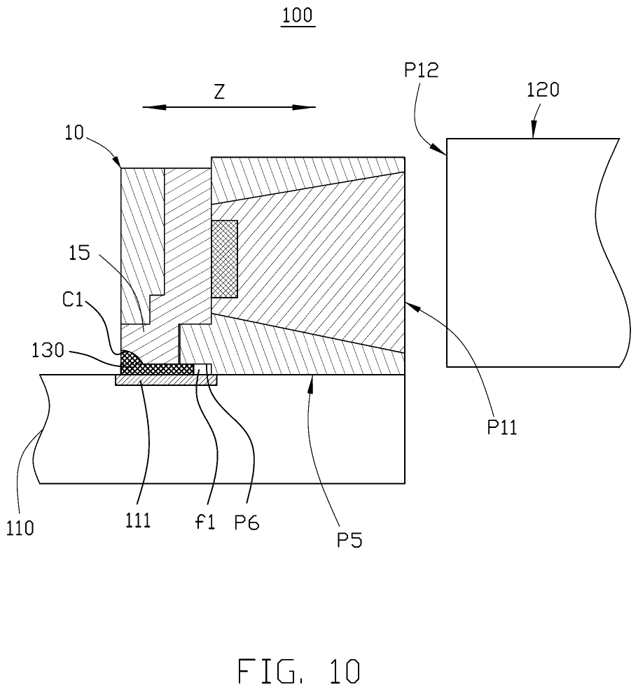

The electrical contact terminal 15 has a first exposed surface P8 exposed from the bottom surface P2 of the packaging body 13 and a second exposed surface P9 exposed from the second surface region P6. The electrical contact terminal 15 has a cut C1 penetrating through the first exposed surface P8 and the second exposed surface P9. The cut C1 can increase a soldering surface of the electrical contact terminal 15, improving soldering reliability. Additionally, a space provided by the cut C1 can accommodate solder 130 (shown in FIG. 10), the space reduces the possibility of solder 130 overflowing from the first exposed surface P8 and the second exposed surface P9.

Optionally, a shape of the cut C1 is a quarter of a sphere, a center of the cut C1 is located on an intersection line L1 between the first exposed surface P8 and the second exposed surface P9. This shape of the cut C1 is beneficial for accommodating solder 130 and provides a larger soldering surface.

The electrical contact terminal 15 protrudes from a side of the conductive plate 24 and protrudes toward the bottom surface P2 of the packaging body 13. The conductive structure 11 further includes at least one exposed block 19, the at least one exposed block 19 protrudes outward from a side surface of the conductive plate 24, and the at least one exposed block 19 is exposed from the outer side surface P3 of the packaging body 13. For example, as shown in FIG. 7, the conductive plate 24 of the positive terminal part 16 of the conductive structure 11 is generally rectangular, the electrical contact terminal 15 and two exposed blocks 19 protruding outward from three edges of the rectangular conductive plate 24, while the other edge of the rectangular conductive plate 24 corresponds to the negative terminal part 17 (shown in FIG. 3).

Referring to FIG. 8, when the conductive structure 11 is encapsulated in the packaging body 13, the electrical contact terminals 15 and exposed blocks 19 of both positive terminal part 16 and negative terminal part 17 are exposed on various sides of the packaging body 13, which helps ensure reliable bonding between the packaging body 13 and the conductive structure 11 on all sides, and facilitates heat dissipation of the conductive structure 11 on all sides of the packaging body 13, improving the overall integrity and heat dissipation capability of the LED packaging structure 10.

Referring again to FIGS. 6 and 7, optionally, the conductive plate 24 of this embodiment includes a base plate 20 and a protruding part 21. The protruding part 21 protrudes downward from a side of the base plate 20, and the electrical contact terminal 15 protrudes outward from a surface of a side of the protruding part 21 away from the base plate 20, forming a three-level stepped shape. The base plate 20 and the protruding part 21 of the conductive plate 24 form a three-level stepped shape, so that the packaging body 13 formed by injection molding also has a stepped shape at the junction with the electrical contact terminal 15, which increases the contact area between the conductive plate 24 and the packaging body 13 and facilitates reliable bonding between the conductive plate 24 and the packaging body 13. Moreover, it is also beneficial to ensure the accuracy of the relative position between the packaging body 13 and the conductive plate 24 by the step limit between the packaging body 13 and the conductive plate 24. Two exposed blocks 19 are located on adjacent sides of the base plate 20, which facilitates mutual positioning between the conductive plate 24 and the packaging body 13 in different directions, and helps to avoid separation between the conductive plate 24 and the package 13.

Referring to FIGS. 3 and 4, in this embodiment, the packaging body 13 includes a first part 22 and a second part 23, where the first part 22 is located on a side of the second part 23 along a thickness direction Z (parallel to the light-emitting direction of the LED chip 12). The conductive structure 11 is encapsulated in the first part 22, and the second part 23 protrudes outward laterally relative to the first part 22, making the outer side surface P3 of the packaging body 13 step-shaped. The conductive structure 11 has a support surface P10 away from the bottom surface P2 of the packaging body 13. The second part 23 is provided with a receiving hole K1. The receiving hole K1 penetrates through the second part 23 in the thickness direction Z, and the receiving hole K1 penetrates to the support surface P10. The LED chip 12 is supported on the support surface P10. Additionally, the receiving hole K1 is filled with a sealing body 14 to seal the LED chip 12 within the receiving hole K1. In this embodiment, the support surface P10 of the conductive plate 24 is coplanar with the step surface P7, which better facilitates thermal stress release during packaging or use of the LED packaging structure 10.

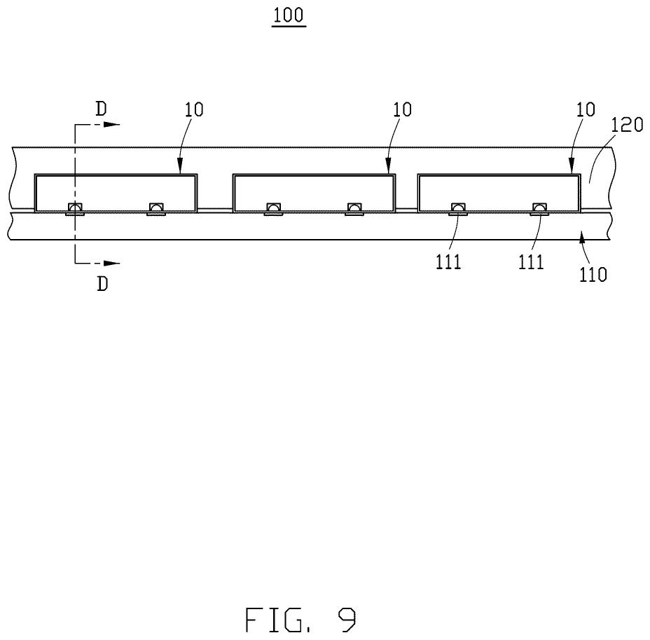

FIG. 9 is a schematic view of the light emitting assembly 100 according to this embodiment. FIG. 10 is a sectional view along line D-D shown in FIG. 9.

Referring to FIGS. 9 and 10, this embodiment also provides a light emitting assembly 100. The light emitting assembly 100 can be, for example, an LED lightbar.

In this embodiment, the light emitting assembly 100 includes a circuit board 110 and at least one of the LED packaging structures 10. The circuit board 110 can be a flexible circuit (FPC) board or a rigid PCB. The circuit board 110 has pads 111 for solder connection with the electrical contact terminals 15 of the LED packaging structure 10 using solder 130.

For example, the circuit board 110 is strip-shaped, and the light emitting assembly 100 includes multiple LED packaging structures 10 arranged at intervals along a length direction of the circuit board 110.

The electrical contact terminals 15 of the LED packaging structure 10 are soldered and connected to the pads 111 of the circuit board 110 to electrically connect the LED chip 12 to the circuit board 110.

Optionally, the light emitting assembly 100 further includes a light guide plate 120, where the light incident surface P12 of the light guide plate 120 corresponds to the light emitting surface P11 of the LED packaging structure 10. Thus, light emitted from the LED packaging structure 10 can be guided by the light guide plate 120.

When the LED packaging structure 10 of this embodiment is mounted on the circuit board 110, since the first surface region P5 is stacked on the circuit board 110, and the second surface region P6 is recessed relative to the first surface region P5, a gap f1 is formed between the second surface region P6 and the circuit board 110. The electrical contact terminal 15 is exposed from the second surface region P6. Thus, when the electrical contact terminal 15 is soldered to the circuit board 110 using solder 130, the first surface region P5 can be evenly stacked on the circuit board 110, and if excess solder 130 is applied during soldering, the excess solder 130 can be accommodated in the gap f1, preventing the excess solder 130 from lifting the second surface region P6 and causing uneven mounting of the LED packaging structure 10 on the circuit board 110.

Moreover, for the electrical contact terminal 15 with the cut C1, excess solder 130 can also be accommodated in the cut C1, helping prevent solder 130 overflow, and the large soldering surface between the solder 130 and the electrical contact terminal 15 helps ensure reliable soldering between the electrical contact terminal 15 and the circuit board 110.

Moreover, due to different materials of the electrical contact terminal 15 (such as metal) and the packaging body 13 (such as plastic), the LED packaging structure 10 may experience different deformation amounts when heated during packaging or use, causing the electrical contact terminal 15 to protrude from the second surface region P6 and making it uneven. This embodiment addresses this by having the second surface region P6 recessed relative to the first surface region P5, allowing the gap f1 between the second surface region P6 and the circuit board 110 to accommodate any protruding electrical contact terminal 15, preventing uneven mounting of the LED packaging structure 10 due to unevenness of the electrical contact terminal 15.

Thus, the LED packaging structure 10 ensures even mounting on the circuit board 110, ensuring that light emitted from the LED packaging structure 10 enters the light guide plate 120 in a correct direction (such as the direction perpendicular to the light incident surface P12), improving the light emitting assembly 100's lighting effect (such as lighting uniformity).

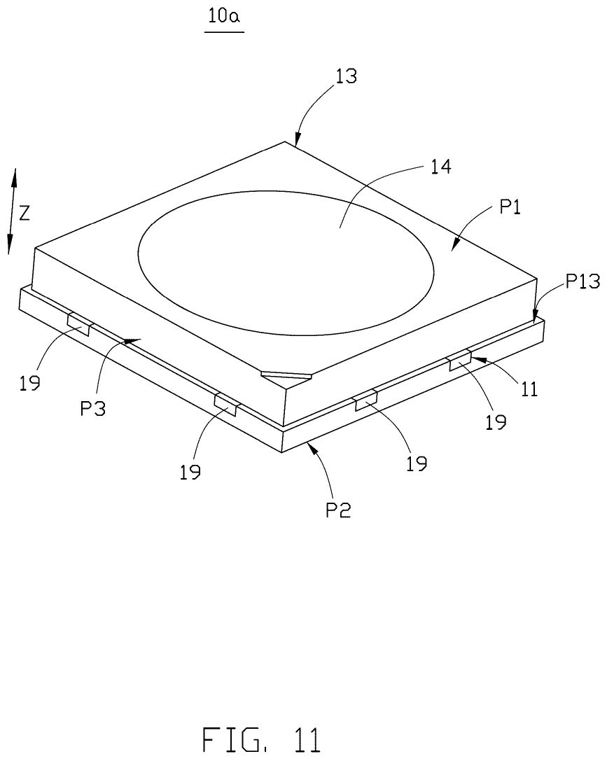

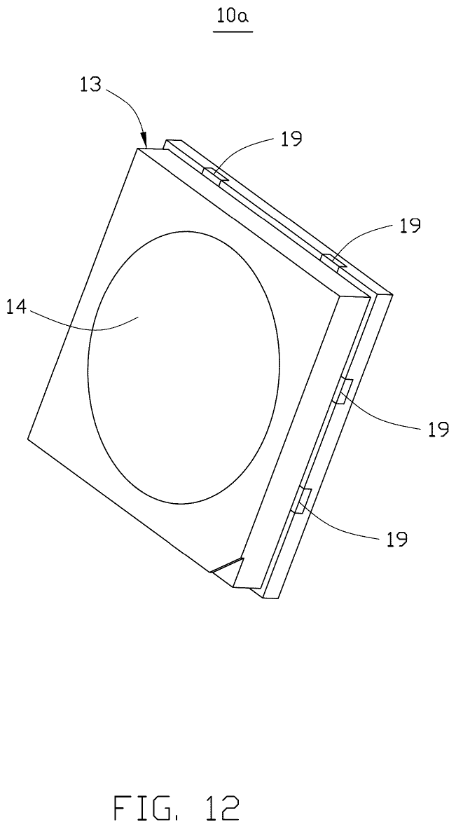

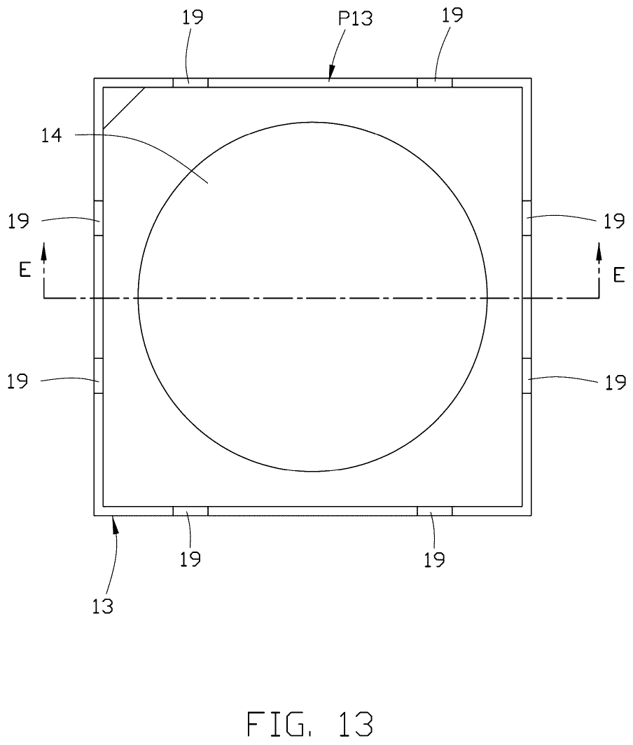

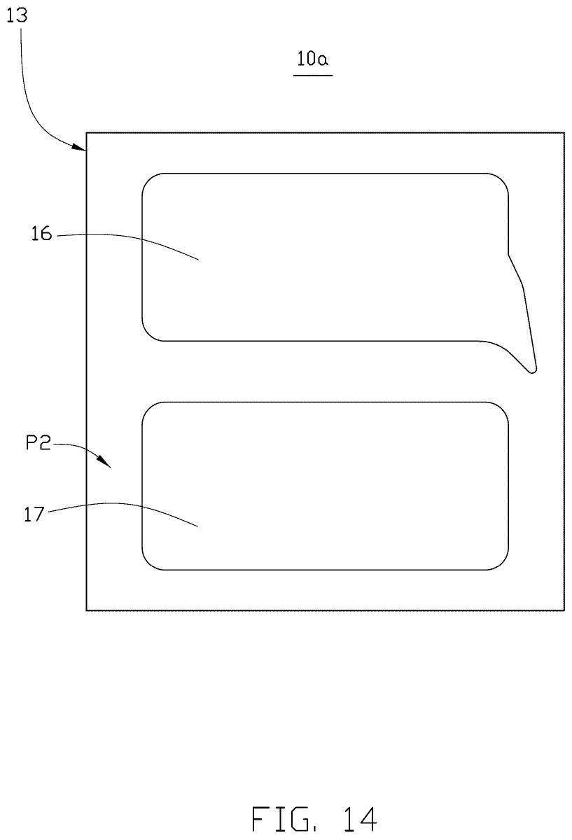

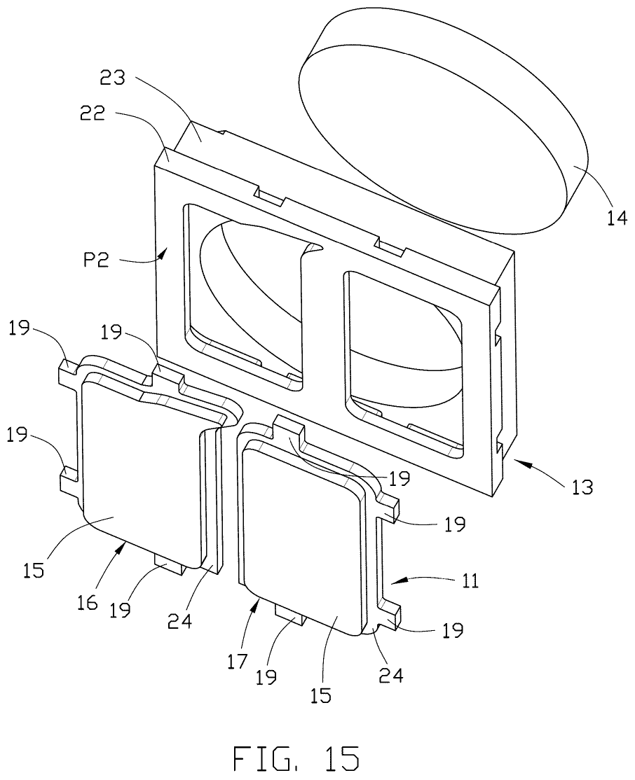

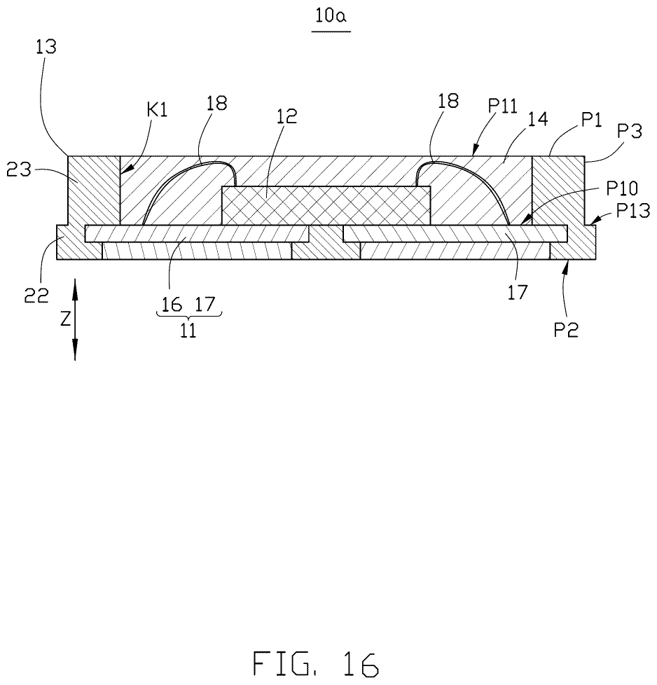

FIG. 11 is a perspective view of an LED packaging structure 10a according to another embodiment. FIG. 12 is another perspective view of the LED packaging structure 10a shown in FIG. 11. FIG. 13 is a top view of the LED packaging structure 10a shown in FIG. 11. FIG. 14 is a bottom view of the LED packaging structure 10a shown in FIG. 11. This LED packaging structure 10a is a top-emitting LED. FIG. 15 is an exploded view of the LED packaging structure 10a shown in FIG. 11. FIG. 16 is a sectional view along line E-E of the LED packaging structure 10a shown in FIG. 13.

Referring to FIGS. 11-16, the LED packaging structure 10a includes a conductive structure 11, an LED chip 12, a packaging body 13, and a sealing body 14. The LED chip 12 is electrically connected to the conductive structure 11, for example, through conductive wires 18. The packaging body 13 encapsulates the conductive structure 11. The packaging body 13 has opposing top surface P1 and bottom surface P2 along the LED chip 12, and an outer side surface P3 connecting between the top surface P1 and the bottom surface P2; the outer side surface P3 is in a step shape.

The conductive structure 11 includes two separated parts, one being the positive terminal part 16 for connecting to a positive electrode of the LED chip 12, and the other being the negative terminal part 17 for connecting to a negative electrode of the LED chip 12. Both the positive terminal part 16 and the negative terminal part 17 of the conductive structure 11 have a conductive plate 24 and an electrical contact terminal 15. The LED chip 12 is disposed on a side surface of the conductive plate 24 and the LED chip 12 is electrically connected to the conductive plate 24.

The electrical contact terminal 15 protrudes from the side surface of the conductive plate 24 away from the LED chip 12, the electrical contact terminal 15 is exposed from the bottom surface P2 of the packaging body 13; and the electrical contact terminal 15 is recessed circumferentially relative to the conductive plate 24 to make the conductive structure 11 in a step shape.

The conductive structure 11 further includes at least one exposed block 19; the at least one exposed block 19 protrudes outward from a side surface of the conductive plate 24 and the at least one exposed block 19 are exposed from the outer side surface P3 of the packaging body 13.

The outer side surface P3 has a step surface P13 extending in the thickness direction Z of the LED packaging structure 10a, and at least a portion of the exposed blocks 19 is exposed from the step surface P13. This provides a larger exposed area for the exposed blocks 19, improving the heat dissipation capability of the LED packaging structure 10a through the exposed blocks 19.

In this embodiment, the packaging body 13 includes a first part 22 and a second part 23, where the first part 22 is located on a side of the second part 23 along the thickness direction Z (parallel to the light-emitting direction of the LED chip 12) of the LED packaging structure 10. The conductive structure 11 is encapsulated in the first part 22, and the second part 23 is recessed inward relative to the first part 22 along a lateral direction to make the outer side surface P3 of the packaging body 13 in a step shape. The conductive structure 11 has a support surface P10 away from the bottom surface P2 of the packaging body 13. The second part 23 is provided with a receiving hole K1 penetrating through the second part 23 in the thickness direction Z, and the receiving hole K1 penetrates to the support surface P10. The LED chip 12 is supported on the support surface P10. Additionally, the receiving hole K1 is filled with a sealing body 14 to seal the LED chip 12 within the receiving hole K1. In this embodiment, the support surface P10 of the conductive plate 24 is coplanar with the step surface P13, which better facilitates thermal stress release during packaging or use of the LED packaging structure 10a.

The above implementation methods are only used to illustrate the technical solution of this application and not to limit it. Although the application has been described in detail with reference to the preferred implementation methods mentioned above, ordinary technical personnel in the art should understand that modifications or equivalent replacements to the technical solution of this application should not deviate from the spirit and scope of the technical solution of this application.

What is claimed is:

1. An LED packaging structure, comprising:
a conductive structure;
an LED chip electrically connected to the conductive structure; and
a packaging body encapsulating the conductive structure, wherein the packaging body has a top surface and a bottom surface opposite to the top surface, and an outer side surface connecting between the top surface and the bottom surface; a shape of the outer side surface is a step shape;
the conductive structure has an electrical contact terminal, and the electrical contact terminal is exposed from the packaging body.

2. The LED packaging structure according to claim 1, wherein:
the LED packaging structure is a side-emitting LED;
the outer side surface of the packaging body comprises a mounting side surface, and the shape of the mounting side surface is step shape;
the mounting side surface comprises a first surface region, a second surface region and a step surface connects the first surface region and the second surface region;
the second surface region is recessed relative to the first surface region, such that when the first surface region is stacked on a circuit board, a gap is formed between the second surface region and the circuit board;
the electrical contact terminal is exposed from the second surface region.

3. The LED packaging structure according to claim 2, wherein:
the electrical contact terminal is located at an intersection between the bottom surface and the second surface region of the packaging body, and the electrical contact terminal is exposed from both the bottom surface and the second surface region of the packaging body.

4. The LED packaging structure according to claim 3, wherein:
the electrical contact terminal comprises a first exposed surface and a second exposed surface, the first exposed surface is exposed from the bottom surface of the packaging body, the second exposed surface is exposed from the second surface region;
the electrical contact terminal has a cut, the cut penetrates through the first exposed surface and the second exposed surface.

5. The LED packaging structure according to claim 4, wherein:
a shape of the cut is a quarter of a sphere, and a center of the sphere is located on an intersection line between the first exposed surface and the second exposed surface.

6. The LED packaging structure according to claim 4, wherein:
the conductive structure comprises a conductive plate; the LED chip is disposed on a side surface of the conductive plate and the LED chip is electrically connected to the conductive plate;
the electrical contact terminal protrudes from a side of the conductive plate and protrudes toward the bottom surface of the packaging body;
the conductive structure further comprises at least one exposed block; the at least one exposed block protrudes outward from a side surface of the conductive plate and is exposed from the outer side surface of the packaging body.

7. The LED packaging structure according to claim 2, wherein:
the packaging body comprises a first part and a second part, the first part is located at one side of the second part along a thickness direction of the LED packaging structure;
the conductive structure is encapsulated in the first part, the second part protrudes outward or is recessed inward relative to the first part along a lateral direction thereby defining the step shape of the outer side surface of the packaging body;
the conductive structure has a support surface away from the bottom surface of the packaging body;
the second part is provided with a receiving hole penetrating through the second part in the thickness direction of the LED packaging structure, the receiving hole penetrates to the support surface;
the LED chip is supported on the support surface; and the receiving hole is filled with a sealing body.

8. The LED packaging structure according to claim 1, wherein:
the LED packaging structure is a top-emitting LED;
the conductive structure comprises a conductive plate, the LED chip is disposed on one side surface of the conductive plate and is electrically connected to the conductive plate;
the electrical contact terminal protrudes from a side surface of the conductive plate away from the LED chip and is exposed from the bottom surface of the packaging body;
and the electrical contact terminal is recessed circumferentially relative to the conductive plate to make the conductive structure in a step shape;
the conductive structure further comprises at least one exposed block; the at least one exposed block protrudes outward from a side surface of the conductive plate and is exposed from the outer side surface of the packaging body;
the outer side surface has a step surface extending in a thickness direction of the LED packaging structure, and at least a portion of the at least one exposed block is exposed from the step surface.

9. The LED packaging structure according to claim 8, wherein:
the packaging body comprises a first part and a second part, the first part is located at one side of the second part along a thickness direction of the LED packaging structure;
the conductive structure is encapsulated in the first part, the second part protrudes outward or is recessed inward relative to the first part along a lateral direction thereby defining the step shape of the outer side surface of the packaging body;
the conductive structure has a support surface away from the bottom surface of the packaging body;
the second part is provided with a receiving hole penetrating through the second part in the thickness direction of the LED packaging structure, the receiving hole penetrates to the support surface;
the LED chip is supported on the support surface; and the receiving hole is filled with a sealing body.

10. A light emitting assembly, comprising:
a circuit board; and
at least one LED packaging structure comprising:
a conductive structure;
an LED chip electrically connected to the conductive structure; and
a packaging body encapsulating the conductive structure, wherein the packaging body has a top surface and a bottom surface opposite to the top surface, and an outer side surface connecting between the top surface and the bottom surface; a shape of the outer side surface is a step shape;
the conductive structure has an electrical contact terminal, and the electrical contact terminal is exposed from the packaging body;
wherein the electrical contact terminal of the LED packaging structure is soldered to the circuit board to electrically connect the LED chip to the circuit board.

11. The light emitting assembly according to claim 9, wherein:
the light emitting assembly further comprises a light guide plate, and a light incident surface of the light guide plate faces towards a light emitting surface of the LED packaging structure.

12. The light emitting assembly according to claim 10, wherein:
the LED packaging structure is a side-emitting LED;
the outer side surface of the packaging body comprises a mounting side surface, and the shape of the mounting side surface is step shape;
the mounting side surface comprises a first surface region, a second surface region and a step surface connects the first surface region and the second surface region;
the second surface region is recessed relative to the first surface region, such that when the first surface region is stacked on a circuit board, a gap is formed between the second surface region and the circuit board;
the electrical contact terminal is exposed from the second surface region.

13. The light emitting assembly according to claim 12, wherein:
the electrical contact terminal is located at an intersection between the bottom surface and the second surface region of the packaging body, and the electrical contact terminal is further exposed from the bottom surface of the packaging body.

14. The light emitting assembly according to claim 13, wherein:
the electrical contact terminal comprises a first exposed surface and a second exposed surface, the first exposed surface is exposed from the bottom surface of the packaging body, the second exposed surface is exposed from the second surface region;
the electrical contact terminal has a cut, the cut penetrates through the first exposed surface and the second exposed surface.

15. The light emitting assembly according to claim 14, wherein:
a shape of the cut is a quarter of a sphere, and a center of the sphere is located on an intersection line between the first exposed surface and the second exposed surface.

16. The light emitting assembly according to claim 14, wherein:
the conductive structure comprises a conductive plate; the LED chip is disposed on a side surface of the conductive plate and the LED chip is electrically connected to the conductive plate;
the electrical contact terminal protrudes from a side of the conductive plate and protrudes toward the bottom surface of the packaging body;
the conductive structure further comprises at least one exposed block; the at least one exposed block protrudes outward from a side surface of the conductive plate and is exposed from the outer side surface of the packaging body.

17. The light emitting assembly according to claim 12, wherein:
the packaging body comprises a first part and a second part, the first part is located at one side of the second part along a thickness direction of the LED packaging structure;
the conductive structure is encapsulated in the first part, the second part protrudes outward or is recessed inward relative to the first part along a lateral direction thereby defining the step shape of the outer side surface of the packaging body;
the conductive structure has a support surface away from the bottom surface of the packaging body;
the second part is provided with a receiving hole penetrating through the second part in the thickness direction of the LED packaging structure, the receiving hole penetrates to the support surface;
the LED chip is supported on the support surface; and the receiving hole is filled with a sealing body.

18. The light emitting assembly according to claim 10, wherein:
the LED packaging structure is a top-emitting LED;
the conductive structure comprises a conductive plate, the LED chip is disposed on one side surface of the conductive plate and is electrically connected to the conductive plate;
the electrical contact terminal protrudes from a side surface of the conductive plate away from the LED chip and is exposed from the bottom surface of the packaging body;
and the electrical contact terminal is recessed circumferentially relative to the conductive plate to make the conductive structure in a step shape;
the conductive structure further comprises at least one exposed block; the at least one exposed block protrudes outward from a side surface of the conductive plate and is exposed from the outer side surface of the packaging body;
the outer side surface has a step surface extending in a thickness direction of the LED packaging structure, and at least a portion of the at least one exposed block is exposed from the step surface.

19. The light emitting assembly according to claim 18, wherein:
the packaging body comprises a first part and a second part, the first part is located at one side of the second part along a thickness direction of the LED packaging structure;
the conductive structure is encapsulated in the first part, the second part protrudes outward or is recessed inward relative to the first part along a lateral direction thereby defining the step shape of the outer side surface of the packaging body;
the conductive structure has a support surface away from the bottom surface of the packaging body;
the second part is provided with a receiving hole penetrating through the second part in the thickness direction of the LED packaging structure, the receiving hole penetrates to the support surface;
the LED chip is supported on the support surface; and the receiving hole is filled with a sealing body.

20. The light emitting assembly according to claim 10, wherein:
the circuit board has a pad, the electrical contact terminal is soldered to the pad.
